(19) United States
(12) Patent Application Publication
(10) Pub. No.: US 2025/0377694 A1
(43) Pub. Date: Dec. 11, 2025

(54) WINDOW, DISPLAY DEVICE, ELECTRONIC DEVICE, AND METHOD OF MANUFACTURING THE WINDOW

(71) Applicant: Samsung Display Co., Ltd., Yongin-Si (KR)

(72) Inventors: TAEWOO PARK, Yongin-si (KR); JEONGWEON SEO, Yongin-si (KR); GWANGTAEK LEE, Yongin-si (KR)

(21) Appl. No.: 19/228,221

(22) Filed: Jun. 4, 2025

(30) Foreign Application Priority Data
Jun. 5, 2024 (KR) 10-2024-0073833

(51) Int. Cl. G06F 1/16; C08J 7/12

(52) U.S. Cl. CPC G06F 1/1656; C08J 7/12; G06F 1/1618

(57) ABSTRACT

A display device, which includes a folding region with respect to an imaginary folding axis on a plane and a non-folding region adjacent to the folding region, includes a display panel and a window disposed on the display panel. The window includes a pattern glass, including a patterned portion which corresponds to the folding region and a non-patterned portion which is adjacent to the patterned portion and corresponds to the non-folding region, and a first resin layer disposed on the pattern glass, a plurality of first groove patterns are defined on an upper surface of the patterned portion, and the first resin layer includes a plurality of first filling patterns respectively filling the plurality of first groove patterns, and a first flat portion directly disposed on the plurality of first filling patterns and the patterned portion.

### CROSS-REFERENCE TO RELATED APPLICATIONS

This U.S. non-provisional patent application claims priority under 35 U.S.C. § 119 of Korean Patent Application No. 10-2024-0073833, filed on Jun. 5, 2024, the entire contents of which are hereby incorporated by reference.

### BACKGROUND

The present disclosure relates to a window, a display device including the same, and a method of manufacturing the window, and more particularly, to a foldable window, a display device including the same, and a method of manufacturing the foldable window.

A display device provides information to users by displaying various images on a display screen. Generally, a display device displays information within an allocated screen.

Recently, flexible display devices including a foldable flexible display panel are being developed. Unlike a rigid display device, a flexible display device may be foldable, rollable, or bendable. The flexible display device deformable into various shapes may be portable regardless of a typical display screen size, thereby improving user convenience.

### SUMMARY

The present disclosure may provide a window having excellent visibility and improved manufacturing efficiencies.

The present disclosure may provide a display device including the window having excellent visibility and improved manufacturing efficiencies.

The present disclosure may also provide a method of manufacturing the window having improved efficiencies during the manufacturing thereof.

An embodiment of an electronic device comprises a display device including a folding region with respect to an imaginary folding axis on a plane and a non-folding region adjacent to the folding region; and a power module supplying power to the display device, the display device including: a display panel; and a window disposed on the display panel, wherein the window includes a pattern glass, including a patterned portion which corresponds to the folding region and a non-patterned portion which is adjacent to the patterned portion and corresponds to the non-folding region, and a first resin layer disposed on the pattern glass, a plurality of first groove patterns are defined on an upper surface of the patterned portion, and the first resin layer includes a plurality of first filling patterns respectively filling the plurality of first groove patterns, and a first flat portion directly disposed on the plurality of first filling patterns and the patterned portion.

In an embodiment, the first resin layer may include an organic material, and the organic material may include at least one of a urethane-based resin, an epoxy-based resin, a polyimide-based resin, a polyester-based resin, a polyether-based resin, an acrylate-based resin, or an ABS resin.

In an embodiment, the organic material may include an ultraviolet curable resin.

In an embodiment, the first resin layer may not include the organic material at least a portion of which is oxidized.

In an embodiment, the first flat portion may entirely overlap the folding region.

In an embodiment, the first flat portion may have a thickness of about 0.01 μm to about 0.2 μm.

In an embodiment, the imaginary folding axis may extend in a first direction, the non-folding region may include a first non-folding region and a second non-folding region spaced apart from each other in a second direction perpendicular to the first direction with the folding region therebetween, and the plurality of first groove patterns may be arranged to be spaced apart from each other in the second direction.

In an embodiment, the window may further include a second resin layer disposed on a lower part of the pattern glass, a plurality of second groove patterns may be defined on a lower surface of the patterned portion, and the second resin layer may include a plurality of second filling patterns respectively filling the plurality of second groove patterns, and a second flat portion directly disposed below the plurality of second filling patterns and the patterned portion.

In an embodiment, the window may further include a window protective layer disposed on the first resin layer.

In an embodiment, the display device may further include an optical layer disposed between the window and the display panel.

An embodiment of a window includes: a pattern glass including a patterned portion in which a plurality of first groove patterns are defined on an upper surface and at least a portion of which is folded, and a non-patterned portion adjacent to the patterned portion; and a first resin layer disposed on the pattern glass, wherein the first resin layer includes a plurality of first filling patterns each of filling each of the plurality of first groove patterns, and a first flat portion directly disposed on the plurality of first filling patterns and the patterned portion.

An embodiment of a method of manufacturing a window includes: providing a pattern glass including a patterned portion in which a plurality of groove patterns are defined on one surface and at least a portion of which is folded on a plane, and a non-patterned portion adjacent to the patterned portion; providing, below the pattern glass, a stage in which a plurality of recessed patterns respectively corresponding to the plurality of groove patterns are defined on one surface; applying a resin on the one surface of the stage; forming a preliminary resin layer by moving the pattern glass in a direction of getting closer to the stage and pressurizing at least some of the resin; forming a resin layer by curing the preliminary resin layer; and separating the stage from the pattern glass and the resin layer.

In an embodiment, surfaces of the plurality of recessed patterns may each include a hydrophobic material.

In an embodiment, the plurality of recessed patterns may each have a contact angle of about 150 degrees to about 180 degrees with respect to water.

In an embodiment, a contact angle of each of the plurality of recessed patterns with respect to the resin may be greater than a contact angle of each of the plurality of groove patterns with respect to the resin.

In an embodiment, the plurality of recessed patterns may each have a micro unevenness defined therein.

In an embodiment, the preliminary resin layer may include: a plurality of preliminary filling patterns respectively filling the plurality of groove patterns; and a preliminary flat portion directly disposed below the plurality of preliminary filling patterns and the patterned portion.

In an embodiment, the forming of the resin layer by curing the preliminary resin layer may include: forming a plurality of filling patterns by curing each of the plurality of preliminary filling patterns; and forming a flat portion by curing the preliminary flat portion.

In an embodiment, the forming of the resin layer by curing the preliminary resin layer may include photocuring the preliminary resin layer by irradiating the pattern glass with ultraviolet rays.

In an embodiment, the forming of the resin layer by curing the preliminary resin layer may include photocuring the preliminary resin layer by irradiating a lower part of the stage with ultraviolet rays, and the stage may have a transmittance of about 90% or more with respect to the ultraviolet rays.

An embodiment of an electronic device includes a display device including a folding region folded with respect to an imaginary folding axis on a plane and a non-folding region adjacent to the folding region and a housing disposed below the display device and accommodating the display device. The display device includes a display panel and a window disposed on the display panel. The window includes a pattern glass including a patterned portion which corresponds to the folding region and a non-patterned portion which is adjacent to the patterned portion and corresponds to the non-folding region, and a first resin layer disposed on the pattern glass. A plurality of first groove patterns are defined on an upper surface of the patterned portion, and the first resin layer includes a plurality of first filling patterns respectively filling the plurality of first groove patterns, and a first flat portion directly disposed on the plurality of first filling patterns and the patterned portion.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1A is a block diagram of an electronic device according to an embodiment of the invention.

FIG. 1B are schematic views of electronic devices according to various embodiments of the invention.

FIG. 1C is a perspective view of a display device according to an embodiment of the inventive concept;

FIGS. 2A, 2B, 2C, and 2D are views illustrating a state in which a display device illustrated in FIG. 1C is folded;

FIG. 3A is a perspective view illustrating an unfolded state of a display device according to an embodiment of the inventive concept;

FIGS. 3B and 3C are views illustrating a state in which a display device illustrated in FIG. 3A is folded;

FIG. 4 is an exploded perspective view of an electronic device according to an embodiment of the inventive concept;

FIG. 5A is a cross-sectional view of a display device taken along line I-I′ illustrated in FIG. 4;

FIG. 5B is an enlarged cross-sectional view of part A1 illustrated in FIG. 5A;

FIG. 6 is a cross-sectional view illustrating a portion of a cross section of a window according to an embodiment of the inventive concept;

FIG. 7 is a flowchart showing some steps of a method of manufacturing a window according to an embodiment of the inventive concept;

FIGS. 8A to 8E are cross-sectional views illustrating some steps of a method of manufacturing a window according to an embodiment of the inventive concept; and

FIG. 9 is a cross-sectional view illustrating some steps of a method of manufacturing a window according to another embodiment of the inventive concept.

### DETAILED DESCRIPTION

In this specification, it will be understood that when an element (or region, layer, portion, or the like) is referred to as being “on”, “connected to” or “coupled to” another element, it may be directly disposed/connected/coupled to another element, or intervening elements may be disposed therebetween.

Like reference numerals or symbols refer to like elements throughout. Also, in the drawings, the thicknesses, the ratios, and the dimensions of the elements are exaggerated for effective description of the technical contents.

Although the terms first, second, etc., may be used to describe various elements, these elements should not be limited by these terms. These terms are only used to distinguish one element from another element. For example, a first element may be referred to as a second element, and similarly, a second element may also be referred to as a first element without departing from the scope of the inventive concept. The singular forms include the plural forms as well, unless the context clearly indicates otherwise.

Also, the terms such as “below”, “lower”, “above”, “upper” and the like, may be used for describing a relationship of elements illustrated in the figures. It will be understood that the terms have a relative concept and are described on the basis of the orientation depicted in the figures.

It will be understood that the terms “includes” and “comprises”, when used in this specification, specifies the presence of stated features, integers, steps, operations, elements, components, or a combination thereof, but does not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the present disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Hereinafter, embodiments of the inventive concept will be described with reference to the accompanying drawings.

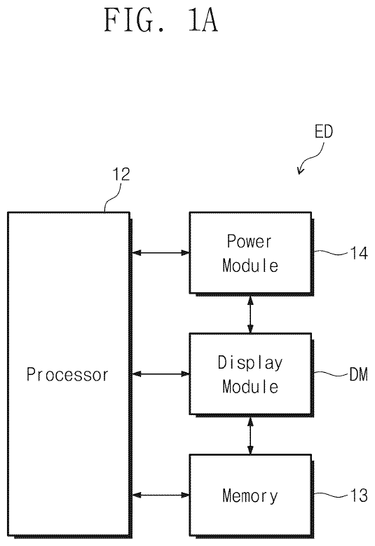

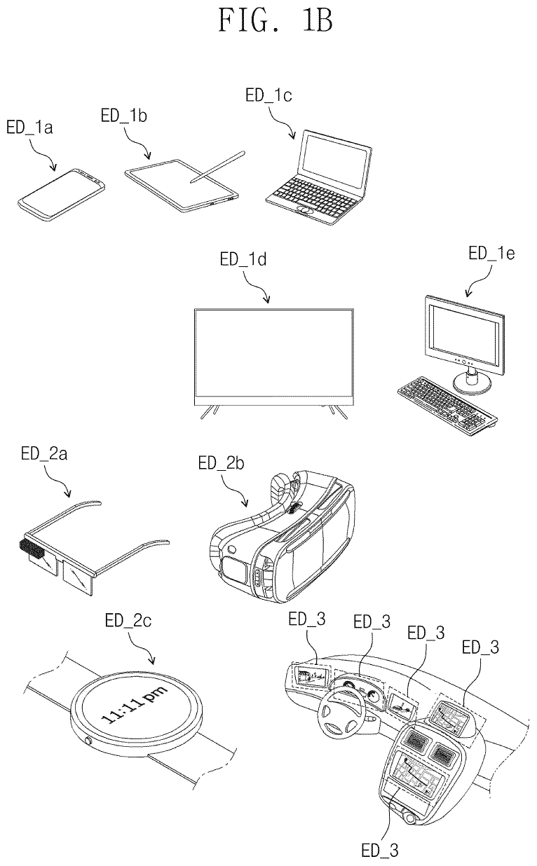

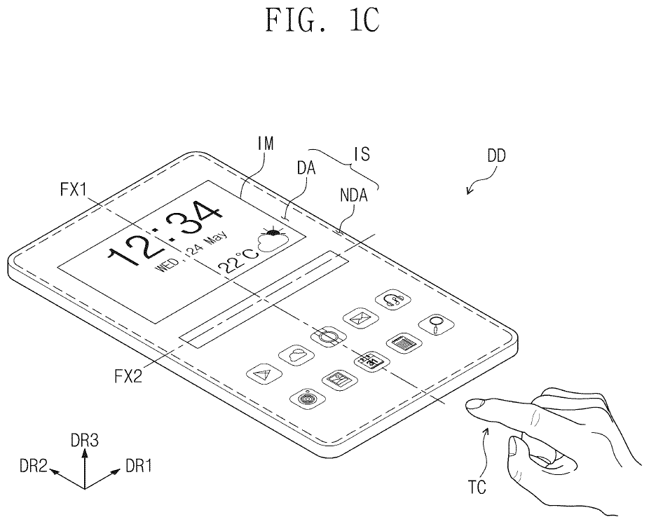

FIG. 1A is a block diagram of an electronic device according to an embodiment. Referring to FIG. 1A, an electronic device ED according to an embodiment may include a display module DM, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 15 may store data information required for the operation of the processor 12 or the display module DM. When the processor 12 executes an application stored in the memory 15, image data signals and/or input control signals are transmitted to the display module DM, and the display module DM may process the received signal and output image information through a display screen.

The power module 14 may include a power supply module such as a power adapter or a battery device, and a power conversion module that converts power supplied by the power supply module to generate power required for the operation of the electronic device ED.

At least one of the components of the electronic device ED described above may be included in the display device according to the above-described embodiments. In addition, some of the individual modules functionally included in one module may be included in the display device, and others may be separately provided from the display device. For example, the display device may include a display module DM, and the processor 12, the memory 13, and the power module 14 may be provided in the form of other devices within the electronic device ED, rather than the display device.

FIG. 1B shows schematic views of electronic devices according to various embodiments.

Referring to FIG. 1B, various electronic devices to which the display device according to embodiments is applied may include an electronic device for displaying images, such as a smart phone ED_1a, a tablet PC ED_1b, a laptop ED_1c, a TV ED_1d, and a desk monitor ED_1e, a wearable electronic device including a display module such as a smart glasses ED_2a, a head mounted display ED_2b, and a smart watch ED_2c, and a vehicle electronic device ED_3 including a display module such as a center information display (CID) and a room mirror display disposed on an instrument panel, a center fascia, or a dashboard of a vehicle. In addition, these devices are merely provided as embodiments, and other electronic devices may be employed as long as not departing from the inventive concept.

FIG. 1C is a perspective view of a display device according to an embodiment of the inventive concept.

Referring to FIG. 1C, a display device DD may be activated in response to an electrical signal. The display device DD may include various embodiments. For example, the display device DD may be used for a large-sized electronic device such as a television, a monitor, or an outdoor billboard, as well as a medium- and small-sized electronic device such as a personal computer, a laptop computer, a personal digital terminal, a car navigation unit, a game console, a portable electronic device, or a camera. In this embodiment, the display device DD is exemplarily illustrated as a smartphone.

The display device DD may have a rectangular shape which has short sides extending in a first direction DR1 and long sides extending in a second direction DR2 crossing the first direction DR1. However, a shape of the display device DD is not limited thereto, and the display device DD may be provided in various shapes.

The display device DD may be a foldable display device. Specifically, the display device DD according to an embodiment of the inventive concept may be folded with respect to a folding axis extending in a predetermined direction. Hereinafter, a state, in which the display device DD is not folded to be flat, is defined as a first state (that is, a non-folded state), and a state, in which the display device DD is folded with respect to the folding axis, is defined as a second state (that is, a folded state). The folding axis means a rotation axis generated when the display device DD is folded, and may be formed by a mechanical structure of the display device DD.

The folding axis may extend in the first direction DR1 or the second direction DR2. In an embodiment of the inventive concept, the folding axis extending in the second direction DR2 is defined as a first folding axis FX1, and the folding axis extending in the first direction DR1 is defined as a second folding axis FX2. The display device DD may include either of the first folding axis FX1 or the second folding axis FX2. That is, the display device DD may be folded with respect to either of the first folding axis FX1 or the second folding axis FX2.

As illustrated in FIG. 1C, the display device DD may display an image IM on a display surface IS parallel to each of the first direction DR1 and the second direction DR2. The display surface IS, on which the image IM is displayed, may correspond to a front surface of the display device DD. A direction perpendicular to the display surface IS, that is, a thickness direction of the display device DD may be referred to as a third direction DR3. The display device DD may display the image IM in the third direction DR3.

The display surface IS of the display device DD may be divided into a plurality of regions. A display region DA and a non-display region NDA may be defined in the display surface IS of the display device DD.

The display region DA may be a region in which the image IM is displayed, and the image IM may be viewed by a user through the display region DA. The display region DA may have a quadrilateral shape. The non-display region NDA is a region adjacent to the display region DA, and in which the image IM is not displayed. The non-display region NDA may define a bezel region of the display device DD. As an example of the inventive concept, the non-display region NDA may surround the display region DA. Accordingly, a shape of the display region DA may be substantially defined by the non-display region NDA. However, this is exemplarily illustrated. The non-display region NDA may be disposed to be adjacent to only one side of the display region DA, or may be omitted.

The display device DD according to the inventive concept may detect a user's input TC applied from the outside. The user's input TC includes various types of external inputs such as a part of a user's body, light, heat, or pressure. In this embodiment, the user's input TC is illustrated as a user's hand which is applied to the front surface. However, this is exemplarily illustrated, and as described above, the user's input TC may be provided in various forms. Additionally, the display device DD may detect the user's input TC which is applied to a side surface or a rear surface of the display device DD according to a configuration of the display device DD, and is not limited to any one embodiment.

The display device DD may activate the display surface IS not only to detect the user's input TC but also to display the image IM. In this embodiment, it is illustrated that a region, in which the user's input TC is detected, is provided in the display region DA in which the image IM is displayed. However, this is exemplarily illustrated, and a region, in which the user's input TC is detected, may be provided in the non-display region NDA, or in the entire region of the display surface IS.

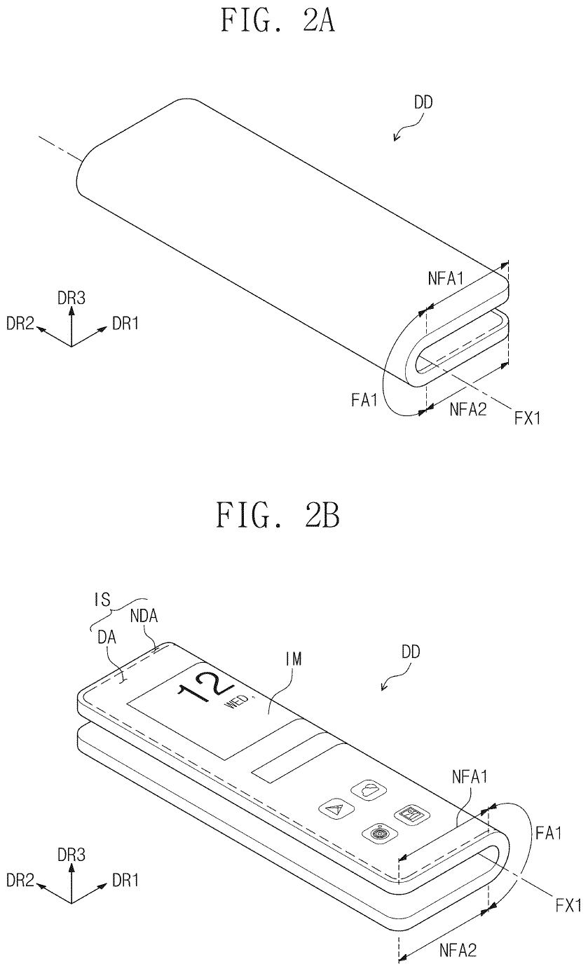

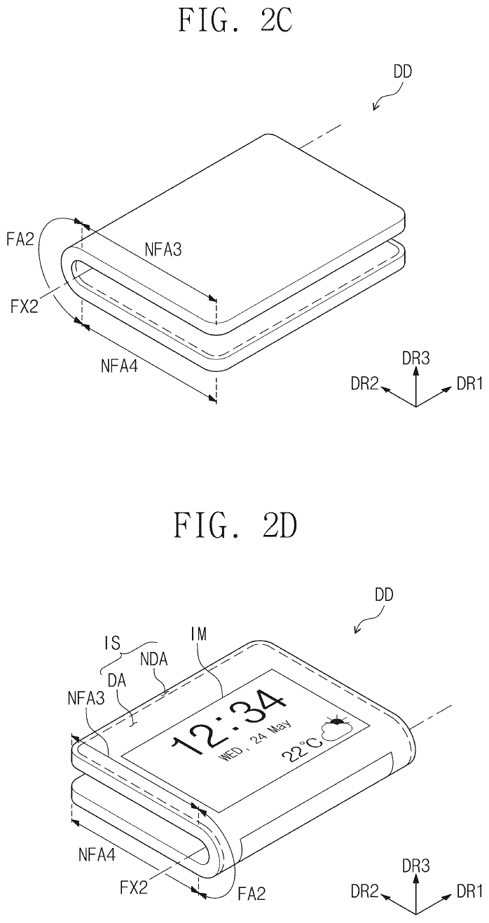

FIGS. 2A to 2D are views illustrating a state in which a display device illustrated in FIG. 1C is folded.

FIG. 2A is a view illustrating a state in which the display device DD illustrated in FIG. 1C is in-folded along a first folding axis FX1, and FIG. 2B is a view illustrating a state in which the display device DD illustrated in FIG. 1C is out-folded along the first folding axis FX1.

FIG. 2C is a view illustrating a state in which the display device DD illustrated in FIG. 1C is in-folded along a second folding axis FX2, and FIG. 2D is a view illustrating a state in which the display device DD illustrated in FIG. 1C is out-folded along the second folding axis FX2.

Referring to FIGS. 2A to 2D, the display device DD may be a foldable display device. The display device DD may be folded with respect to a folding axis extending in a predetermined direction, such as the first folding axis FX1 or the second folding axis FX2.

Referring to FIGS. 2A and 2B, in the display device DD, a plurality of regions may be defined according to operation forms. The plurality of regions may be divided into at least one folding region FA1, and non-folding regions NFA1 and NFA2. The folding region FA1 is defined between the two non-folding regions NFA1 and NFA2.

The folding region FA1 is a region which is folded with respect to the first folding axis FX1 and in which a curvature is substantially formed. In this case, the first folding axis FX1 may extend in the second direction DR2, that is, along a long axis direction of the display device DD. The folding region FA1 is defined as a region which is folded with respect to the first folding axis FX1 and extends in the second direction DR2.

As an example of the inventive concept, the non-folding regions NFA1 and NFA2 may include a first non-folding region NFA1 and a second non-folding region NFA2. The first non-folding region NFA1 is adjacent to one side of the folding region FA1 in the first direction DR1, and the second non-folding region NFA2 is adjacent to the other side of the folding region FA1 in the first direction DR1.

The display device DD may be in-folded or out-folded. The in-folding is defined as a state in which the display device DD is folded such that display surfaces of the respective non-folding regions NFA1 and NFA2 face each other, and the out-folding is defined as a state in which display device DD is folded such that the display surfaces of the respective non-folding regions NFA1 and NFA2 are headed toward the outside.

The display device DD illustrated in FIG. 2A may be in-folded such that the display surface IS (see FIG. 1C) of the first non-folding region NFA1, and the display surface IS (see FIG. 1C) of the second non-folding region NFA2 face each other. As the first non-folding region NFA1 may rotate clockwise along the first folding axis FX1, the display device DD may be in-folded. The first folding axis FX1 may be defined at the center of the display device DD in the first direction DR1 such that the display device DD is in-folded to align the first non-folding region NFA1 and the second non-folding region NFA2.

Referring to FIG. 2B, the display device DD may be out-folded with respect to the first folding axis FX1. The display device DD may display the image IM when the display surface of the first non-folding region NFA1 and the display surface of the second non-folding region NFA2 are exposed to the outside. Additionally, the display surface of the folding region FA1 exposed to the outside may also display the image IM. As illustrated in FIG. 1C, the display device DD may display the image IM in an unfolded state. The first non-folding region NFA1, the second non-folding region NFA2, and the folding region FA1 may respectively display images which independently provide information, or may each display parts of one image which provides one piece of information.

The display device DD may be manufactured so as to be in both an in-folded state and an out-folded state, or to be in either an in-folded state or an out-folded state.

Referring to FIGS. 2C and 2D, the display device DD may be in-folded or out-folded with respect to a second folding axis FX2. The second folding axis FX2 may extend in the first direction DR1, that is, along a short axis direction of the display device DD.

A plurality of regions may be defined in the display device DD according to operation forms. The plurality of regions may be divided into at least one folding region FA2, and non-folding regions NFA3 and NFA4. The folding region FA2 is defined between the two non-folding regions NFA3 and NFA4.

The folding region FA2 is a region which is folded with respect to the second folding axis FX2 and in which a curvature is substantially formed. The folding region FA2 is defined as a region which is folded with respect to the second folding axis FX2 and extends in the first direction DR1.

As an example of the inventive concept, the non-folding regions NFA3 and NFA4 may include a first non-folding region NFA3 and a second non-folding region NFA4. The first non-folding region NFA3 is adjacent to one side of the folding region FA2 in the second direction DR2, and the second non-folding region NFA4 is adjacent to the other side of the folding region FA2 in the second direction DR2.

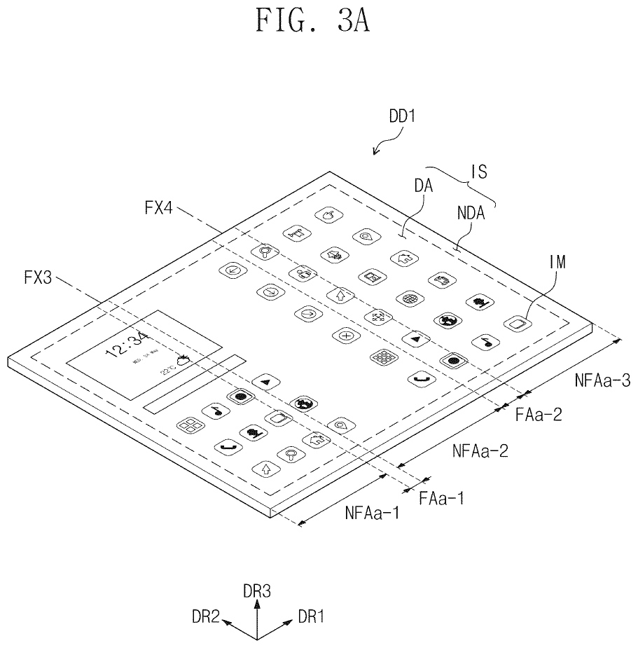

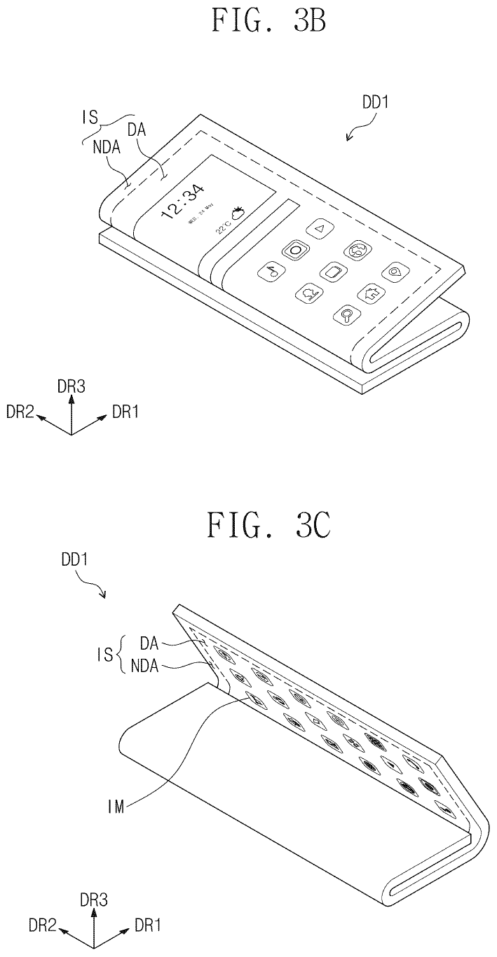

FIG. 3A is a perspective view illustrating an unfolded state of a display device according to an embodiment of the inventive concept. FIGS. 3B and 3C are views illustrating a state in which a display device illustrated in FIG. 3A is multi-folded.

Referring to FIGS. 3A to 3C, a display device DD1 may be a multi-foldable display device. A plurality of folding regions may be defined in the display device DD1. The display device DD1 may include a plurality of folding regions FAa-1 and FAa-2, and a plurality of non-folding regions NFAa-1, NFAa-2, and NFAa-3. As an example of the inventive concept, the display device DD1 may include a first folding region FAa-1, a second folding region FAa-2, a first non-folding region NFAa-1, a second non-folding region NFAa-2, and a third non-folding region NFAa-3. In the first direction DR1, the first folding region FAa-1 is disposed between the first non-folding region NFAa-1 and the second non-folding region NFAa-2, and the second folding region FAa-2 is disposed between the second non-folding region NFAa-2 and the third non-folding region NFAa-3. It is exemplarily illustrated that two folding regions FAa-1 and FAa-2, and three non-folding regions NFAa-1, NFAa-2, and NFAa-3 are included. However, the number of the folding regions FAa-1 and FAa-2, and the non-folding regions NFAa-1, NFAa-2, and NFAa-3 is not limited thereto, and may be increased.

Referring to FIGS. 3A and 3B, the first folding region FAa-1 may be folded with respect to a third folding axis FX3 parallel to the second direction DR2. The first folding region FAa-1 may be in-folded such that a display surface of the second non-folding region NFAa-2 and a display surface of the first non-folding region NFAa-1 face each other. The second folding region FAa-2 may be folded with respect to a fourth folding axis FX4 parallel to the second direction DR2. The second folding region FAa-2 may be out-folded such that a rear surface of the second non-folding region NFAa-2 and a rear surface of the third non-folding region NFAa-3 face each other and a display surface of the third non-folding region NFAa-3 is headed toward the outside.

Referring to FIGS. 3A and 3C, the first folding region FAa-1 may be folded with respect to the third folding axis FX3 parallel to the second direction DR2. The first folding region FAa-1 may be in-folded such that the display surface of the first non-folding region NFAa-1 is disposed inside and the display surface of the second non-folding region NFAa-2 and the display surface of the first non-folding region NFAa-1 face each other. The second folding region FAa-2 may be folded with respect to the fourth folding axis FX4 parallel to the second direction DR2. The second folding region FAa-2 may be in-folded such that a rear surface of the first non-folding region NFAa-1 and the display surface of the third non-folding region NFAa-3 face each other.

In an embodiment of the inventive concept, an out-folding operation and an in-folding operation may be performed simultaneously, and either an in-folding operation or an out-folding operation may only be performed.

Meanwhile, FIGS. 3B and 3C illustrate a state in which the display device DD1 is a multi-folded, but an embodiment of the inventive concept is not limited thereto. The display device DD1 may be folded in various forms.

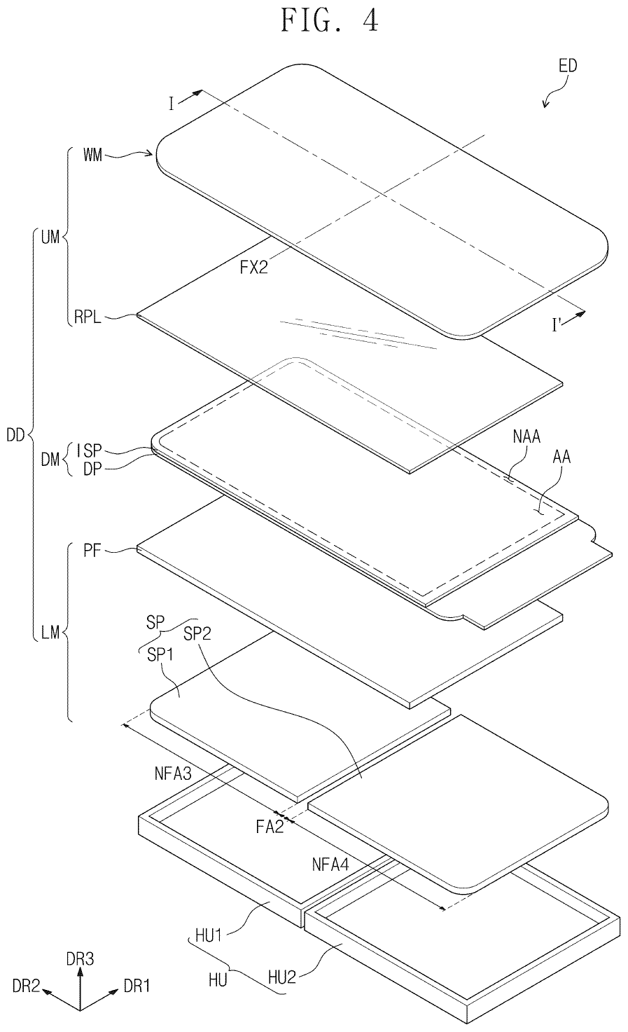

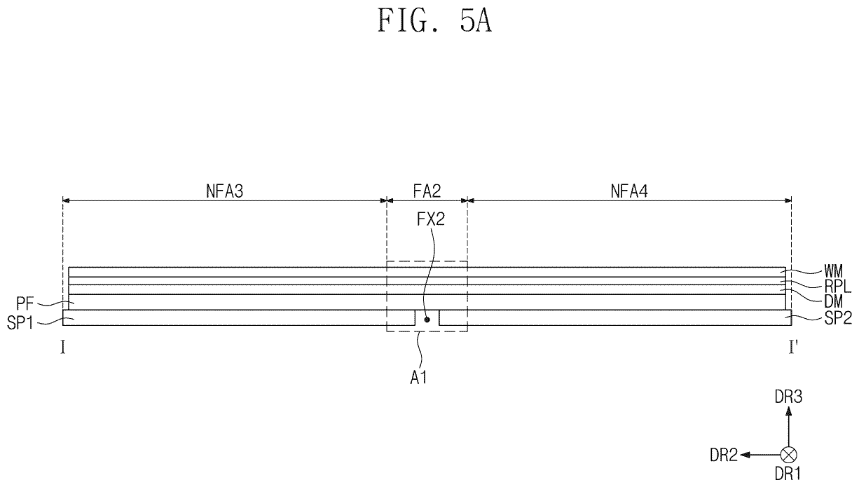

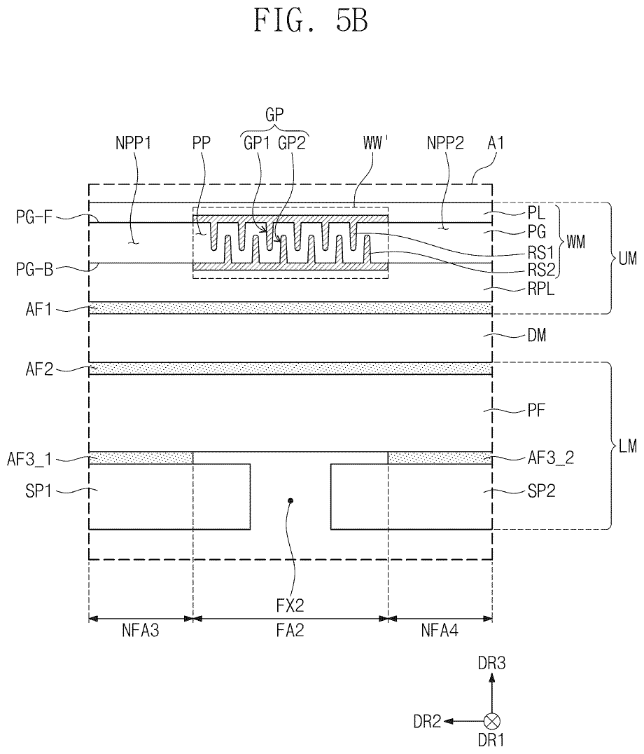

FIG. 4 is an exploded perspective view of an electronic device according to an embodiment of the inventive concept, and FIG. 5A is a cross-sectional view of the display device taken along line I-I of FIG. 4. FIG. 5B is an enlarged cross-sectional view of part A1 illustrated in FIG. 5A.

Referring to FIGS. 4, 5A, and 5B, an electronic device ED according to an embodiment of the inventive concept includes a display device DD and a housing HU. Although not illustrated, the electronic device ED may further include a mechanical structure (or a hinge structure) for controlling a folding operation (or a bending operation) of the display device DD.

The display device DD according to an embodiment of the inventive concept may include a display module DM which displays images, an upper module UM disposed on the display module DM, and a lower module LM disposed below the display module DM. The display module DM may constitute a part of the display device DD, and particularly, images may be generated by the display module DM.

The display module DM may include a display panel DP and an input-sensing unit ISP. The display panel DP according to an embodiment of the inventive concept may be a light-emitting display panel, and is not particularly limited. For example, the display panel DP may be an organic light-emitting display panel, an inorganic light-emitting display panel, or a quantum dot light-emitting display panel. A light-emitting layer of the organic light-emitting display panel may include an organic light-emitting material, and a light-emitting layer of the inorganic light-emitting display panel may include an inorganic light-emitting material. A light-emitting layer of the quantum dot light-emitting display panel may include quantum dots, quantum rods, etc. Hereinafter, the display panel DP is described as an organic light-emitting display panel.

The display panel DP may be a flexible display panel. Accordingly, the display panel DP may be entirely rolled, or folded or unfolded with respect to the folding axis FX2.

The input-sensing unit ISP may be directly disposed on the display panel DP. According to an embodiment of the inventive concept, the input-sensing unit ISP may be formed on the display panel DP through a continuous process. That is, when the input-sensing unit ISP is directly disposed on the display panel DP, an adhesive film is not disposed between the input-sensing unit ISP and the display panel DP. However, an embodiment of the inventive concept is not limited thereto. An adhesive film may be disposed between the input-sensing unit ISP and the display panel DP. In this case, the input-sensing unit ISP and the display panel DP may not be manufactured through a continuous process, but the input-sensing unit ISP may be manufactured through a separate process from the display panel DP and then fixed to an upper surface of the display panel DP by an adhesive film.

The display panel DP generates images, and the input-sensing unit ISP acquires coordinate information about a user's input (for example, a touch event).

The upper module UM may include a window WM disposed on the display module DM. The window WM may include an optically transparent insulating material. Accordingly, images generated from the display module DM pass through the window WM, and may thus be easily recognized by a user. The window WM may include a pattern glass PG, a first resin layer RS1, a second resin layer RS2, and a window protective layer PL.

The pattern glass PG may include a glass material. The pattern glass PG may include a patterned portion PP, and non-patterned portions NPP1 and NPP2. The patterned portion PP may correspond to a folding region FA2, and the non-patterned portions NPP1 and NPP2 may correspond to first and second non-folding regions NFA3 and NFA4. The non-patterned portions NPP1 and NPP2 may include a first non-patterned portion NPP1 corresponding to the first non-folding region NFA3, and a second non-patterned portion NPP2 corresponding to the second non-folding region NFA4. The patterned portion PP may be disposed between the first and second non-patterned portions NPP1 and NPP2.

The pattern glass PG may include an upper surface PG-F and a lower surface PG-B. The upper surface PG-F and the lower surface PG-B mean two surfaces opposed to each other in the pattern glass PG, and for example, may be two surfaces facing each other in the third direction DR3. In the pattern glass PG, a surface adjacent to an anti-reflection layer RPL or the display module DM in the third direction DR3 may be the lower surface PG-B, and a surface adjacent to the window protective layer PL may be the upper surface PG-F.

The patterned portion PP may include a plurality of groove patterns GP. In an embodiment, the plurality of groove patterns GP may include a plurality of first groove patterns GP1 provided on the upper surface PG-F of the pattern glass PG, and a plurality of second groove patterns GP2 provided on the lower surface PG-B of the pattern glass PG. The first groove patterns GP1 may have a shape recessed from the upper surface PG-F of the pattern glass PG toward the lower surface PG-B of the pattern glass PG, and the second groove patterns GP2 may have a shape recessed from the lower surface PG-B of the pattern glass PG toward the upper surface PG-F of the pattern glass PG.

As an example of the inventive concept, when the folding axis FX2 extends in the first direction DR1, the first groove patterns GP1 may be arranged to be spaced apart from each other in the second direction DR2, and the second groove patterns GP2 may be arranged to be spaced apart from each other in the second direction DR2. Alternatively, when the folding axis FX2 extends in the second direction DR2, the first groove patterns GP1 may be arranged to be spaced apart from each other in the first direction DR1, and the second groove patterns GP2 may be arranged to be spaced apart from each other in the first direction DR1.

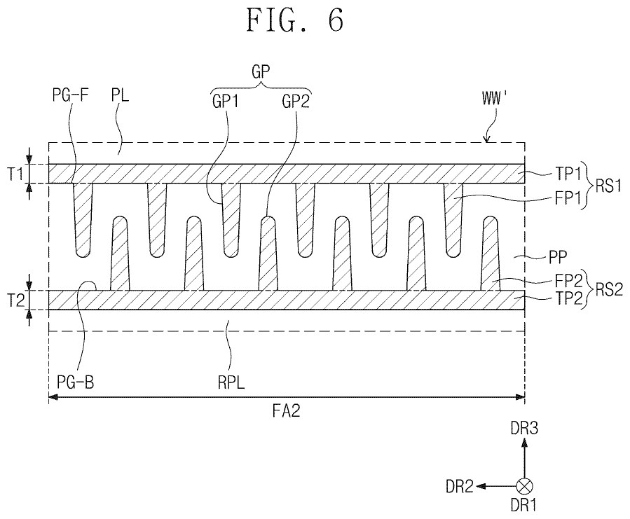

The first resin layer RS1 and the second resin layer RS2 may respectively fill the groove patterns GP. The first resin layer RS1 may fill the first groove patterns GP1, and the second resin layer RS2 may fill the second groove patterns GP2. That is, the first resin layer RS1 may fill spaces recessed due to the first groove patterns GP1, and the second resin layer RS2 may fill spaces recessed due to the second groove patterns GP2. As an example of the inventive concept, the first resin layer RS1 and the second resin layer RS2 may be provided only in the patterned portion PP, and may not be provided in the first and second non-patterned portions NPP1 and NPP2. The details of the first resin layer RS1 and the second resin layer RS2 will be described later with reference to FIG. 6.

The window WM may further include a window protective layer PL. The window protective layer PL may be provided on the pattern glass PG. The window protective layer PL may be provided on the first resin layer RS1. The window protective layer PL may perform a function of protecting the pattern glass PG against an external impact. The window protective layer PL may include a synthetic resin material. As an example of the inventive concept, the window protective layer PL may include at least one selected from a urethane-based resin, an epoxy-based resin, a polyester-based resin, a polyether-based resin, an acrylate-based resin, an acrylonitrile-butadiene-styrene resin (ABS resin), and rubber. Specifically, the window protective layer PL may include at least one of phenylene, polyethyleneterephthalate (PET), polyimide (PI), polyamide (PAI), polyethylene naphthalate (PEN), or polycarbonate (PC).

Although not illustrated in the drawing, the window WM may further include a first window adhesive layer and a second window adhesive layer. The first window adhesive layer may be disposed between the pattern glass PG and the window protective layer PL, or between the first resin layer RS1 and the window protective layer PL, and attach the window protective layer PL to the pattern glass PG or the first resin layer RS1. The second window adhesive layer may bond the window WM and a member disposed below the window WM. The first window adhesive layer and the second window adhesive layer may include optically transparent adhesive materials. For example, the first window adhesive layer and the second window adhesive layer may each include a pressure sensitive adhesive (PSA), an optical clear adhesive (OCA), or an optical clear resin (OCR).

The window WM may be folded or unfolded with respect to the folding axis FX2. That is, a shape of the window WM may be deformed as a shape of the display module DM is deformed. The window WM transmits images from the display module DM as well as reduces external impacts, and thus it is possible to prevent the display module DM from being damaged or malfunctioning due to external impacts. The wording “an external impact” means a force which is applied from the outside, such as pressure or stress, and causes defect to the display module DM.

Additionally, the upper module UM may further include one or more functional layers disposed between the display module DM and the window WM. As an example of the inventive concept, the functional layer may be an anti-reflection layer RPL which blocks reflection for external light.

The anti-reflection layer RPL may prevent elements constituting the display module DM from being viewed from the outside due to external light incident through a front surface of the display device DD. The anti-reflection layer RPL may include a retarder and a polarizer. The retarder may be a film type retarder or a liquid crystal coating type retarder, and may include a λ/2 retarder or a λ/4 retarder. The polarizer may also be a film type polarizer or a liquid crystal coating type polarizer. The film type may include a stretched synthetic resin film, and the liquid crystal coating type may include liquid crystals arranged in a predetermined arrangement. The retarder and polarizer may form one polarizing film. The functional layer may further include a protective film disposed above or below the anti-reflection layer RPL.

The upper module UM may further include a first adhesive film AF1 provided between the anti-reflection layer RPL and the display module DM. The first adhesive film AF1 may include an optically transparent adhesive material. As an example of the inventive concept, the first adhesive film AF1 may include a pressure sensitive adhesive (PSA), an optical clear adhesive (OCA), or an optical clear resin (OCR).

The display module DM may display images in response to an electrical signal, and transmit/receive information about an external input. The display module DM may include an active region AA and a peripheral region NAA. The active region AA may be defined as a region in which images provided from the display module DM are displayed.

The peripheral region NAA is adjacent to the active region AA. For example, the peripheral region NAA may surround the active region AA. However, this is illustrated as an example. The peripheral region NAA may be defined as having various shapes, and is not limited to any one embodiment. According to an embodiment, the active region AA of the display module DM may correspond to at least a portion of the display region DA (see FIG. 1C).

The lower module LM is disposed on a rear surface of the display module DM and includes a support plate SP which supports the display module DM. The support plate SP may include support plates the number of which corresponds to the number of the non-folding regions NFA3 and NFA4. As an example of the inventive concept, the support plate SP may include a first support plate SP1 and a second support plate SP2 disposed to be spaced apart from the first support plate SP1.

The first and second support plates SP1 and SP2 may be disposed to respectively correspond to the first and second non-folding regions NFA3 and NFA4. The first support plate SP1 is disposed to correspond to the first non-folding region NFA3 of the display module DM, and the second support plate SP2 is disposed to correspond to the second non-folding region NFA4 of the display module DM. The first and second support plates SP1 and SP2 may each include a metal material or a plastic material.

In a first state in which the display module DM is flat, the first and second support plates SP1 and SP2 are disposed to be spaced apart from each other in the second direction DR2. In a second state in which the display module DM is folded with respect to the folding axis FX2, the first and second support plates SP1 and SP2 may be disposed to be spaced apart from each other in the third direction DR3.

The first and second support plates SP1 and SP2 may be spaced apart with respect to the folding region FA2. The first and second support plates SP1 and SP2 may partially overlap the folding region FA2. That is, in the second direction DR2, a spacing distance between the first and second support plates SP1 and SP2 may be smaller than a width of the folding region FA2.

The support plate SP may further include a connection module for connecting the first and second support plates SP1 and SP2. The connection module may include a hinge module or an articulated module.

It is illustrated that the support plate SP includes two support plates SP1 and SP2, but an embodiment of the inventive concept is not limited thereto. That is, when a plurality of folding axes FX2 are provided, the support plate SP may include a plurality of support plates separated with respect to the plurality of folding axes FX2. Alternatively, the support plate SP may be provided not to be separated into the first and second support plates SP1 and SP2, but to have an integrated shape. In this case, a bending portion may be provided to the support plate SP corresponding to the folding region FA2. The bending portion may be provided with an opening formed by penetrating the support plate SP or may be provided with a groove recessed from one surface of the support plate SP.

The lower module LM further includes a protective film PF disposed between the display module DM and the support plate SP. The protective film PF may be disposed below the display module DM, and may protect a rear surface of the display module DM. The protective film PF may include a synthetic resin film, for example, a polyimide film or a polyethyleneterephthalate film. However, this is presented as an example, and the protective film PF is not limited thereto.

The lower module LM may further include a second adhesive film AF2 disposed between the protective film PF and the display module DM, and third adhesive films AF3_1 and AF3_2 disposed between the protective film PF and the support plate SP. The protective film PF may be attached to a rear surface of the display module DM via the second adhesive film AF2. As an example of the inventive concept, the third adhesive films AF3_1 and AF3_2 may include a first sub-adhesive film AF3_1, and a second sub-adhesive film AF3_2. The first sub-adhesive film AF3_1 is disposed between the first support plate SP1 and the protective film PF, and the second sub-adhesive film AF3_2 is disposed between the second support plate SP2 and the protective film PF. The first and second sub-adhesive films AF3_1 and AF3_2 may be spaced apart from each other with the folding region FA2 therebetween.

The second and third adhesive films AF2, AF3_1, and AF3_2 may each include an optically transparent adhesive material. As an example of the inventive concept, the second and third adhesive films AF2, AF3_1, and AF3_2 may each include a pressure sensitive adhesive (PSA), an optical clear adhesive (OCA), or an optical clear resin (OCR).

The housing HU is coupled to the display device DD, specifically, to the window WM, and accommodates other modules described above (that is, the display module DM, the lower module LM, etc.). It is illustrated that the housing HU includes first and second housings HU1 and HU2 separated from each other, but an embodiment of the inventive concept is not limited thereto. Although not illustrated, the electronic device ED may further include a hinge structure for connecting the first and second housings HU1 and HU2.

The window WM according to an embodiment of the inventive concept will be described in detail with reference to the accompanying drawings.

FIG. 6 is a cross-sectional view illustrating a portion of a cross section of a window according to an embodiment of the inventive concept. FIG. 6 illustrates, in more detail, a cross section of the window WM (see FIG. 5B), enlarging region WW′ of FIG. 5B.

Referring to FIG. 6, the pattern glass PG (see FIG. 5B) may include the patterned portion PP corresponding to the folding region FA2. The patterned portion PP may include the plurality of groove patterns GP.

The groove patterns GP may have a stripe-like shape extending in a direction (that is, the first direction DR1) parallel to the folding axis FX2 (see FIG. 1C). The groove patterns GP may be arranged to be spaced apart from each other in the second direction DR2. Alternatively, the groove patterns GP may include a plurality of first sub-groove patterns arranged to be spaced apart from each other in the first direction DR1. The first sub-groove patterns may each have a stripe-like shape extending in the second direction DR2.

The plurality of groove patterns GP may include the first groove patterns GP1 having a shape of a groove recessed from the upper surface PG-F of the pattern glass PG, and the second groove patterns GP2 having a shape of a groove recessed from the lower surface PG-B of the pattern glass PG. The first resin layer RS1 and second resin layer RS2 may respectively fill the first groove patterns GP1 and the second groove patterns GP2. The first resin layer RS1 may fill spaces recessed by the first groove patterns GP1, and the second resin layer RS2 may fill spaces recessed by the second groove patterns GP2.

The first resin layer RS1 and the second resin layer RS2 may each include an organic material. The first resin layer RS1 and the second resin layer RS2 may each include an ultraviolet curable resin. As an example of the inventive concept, the organic material included in each of the first resin layer RS1 and the second resin layer RS2 may include at least one selected from a urethane-based resin, an epoxy-based resin, a polyimide-based resin, a polyester-based resin, a polyether-based resin, an acrylate-based resin, an acrylonitrile-butadiene-styrene resin (ABS resin), and rubber. Specifically, the organic material included in each of the first resin layer RS1 and the second resin layer RS2 may include at least one of phenylene, polyethyleneterephthalate (PET), polyimide (PI), polyamide (PAI), polyethylene naphthalate (PEN), or polycarbonate (PC). For example, the first resin layer RS1 and the second resin layer RS2 may each include polyimide. The first resin layer RS1 and the second resin layer RS2 may each include an organic material, and may not include the organic material at least a portion of which is oxidized. That is, during each of processes manufacturing the first resin layer RS1 and the second resin layer RS2, the first resin layer RS1 and the second resin layer RS2 may not be exposed to oxygen.

With respect to light having a first wavelength, refractive indices of the first and second resin layers RS1 and RS2 may be substantially the same as the refractive index of the pattern glass PG (see FIG. 5B). Therefore, the window WM (see FIG. 4) according to an embodiment of the inventive concept may exhibit visibility of the certain level or more even when the pattern glass PG (see FIG. 5B) is included therein. Meanwhile, in this specification, the wording “substantially the same” includes not only a case where components have physically completely the same refractive index, thickness, etc., but also a case where in spite of being identically designed, components have a difference in a refractive index, a thickness, etc., by tolerances which occur during a process. The first wavelength may be about 500 nm to about 600 nm. For example, the first and second resin layers RS1 and RS2, and the pattern glass PG (see FIG. 5B) may all have substantially the same refractive index with respect to green light.

The first resin layer RS1 may include a plurality of first filling patterns FP1 and a first flat portion TP1. The second resin layer RS2 may include a plurality of second filling patterns FP2 and a second flat portion TP2. The plurality of first filling patterns FP1 and the first flat portion TP1 may be formed through the same process and by the same material. The plurality of second filling patterns FP2 and the second flat portion TP2 may be formed through the same process and by the same material.

The plurality of first filling patterns FP1 may be defined to fill the plurality of first groove patterns GP1, respectively. The plurality of first filling patterns FP1 may fill spaces recessed due to the first groove patterns GP1. The plurality of second filling patterns FP2 may be defined to fill the plurality of second groove patterns GP2, respectively. The plurality of second filling patterns FP2 may fill spaces recessed due to the second groove patterns GP2.

The first flat portion TP1 may be directly disposed on the pattern glass PG (see FIG. 5B) and the plurality of first filling patterns FP1. The first flat portion TP1 is directly disposed on the patterned portion PP. The first flat portion TP1 may cover an upper surface of the patterned portion PP, and an upper surface of each of the plurality of first filling patterns FP1. A lower surface of the first flat portion TP1 may be in contact with the upper surface PG-F of the pattern glass PG, or the upper surface of each of the plurality of first filling patterns FP1. The first flat portion TP1 may have a thickness T1 of about 0.01 μm to about 0.2 μm. For example, the first flat portion TP1 may have a thickness T1 of about 0.1 μm to about 0.2 μm. The first flat portion TP1 may correspond to the folding region FA2, and may be disposed so as to entirely overlap the folding region FA2. However, a shape of the first flat portion TP1 is not limited thereto, and in another embodiment, the first flat portion TP1 may be disposed so as to overlap a portion of the folding region FA2. Alternatively, in another embodiment, the first flat portion TP1 may entirely overlap the folding region FA2, and may be disposed so as to overlap a portion of the non-folding regions NFA3 and NFA4 (see FIG. 5B).

The second flat portion TP2 may be directly disposed below the pattern glass PG (see FIG. 5B) and the plurality of second filling patterns FP2. The second flat portion TP2 is directly disposed below the patterned portion PP. The second flat portion TP2 may cover a lower surface of the patterned portion PP, and a lower surface of each of the plurality of second filling patterns FP2. A lower surface of the second flat portion TP2 may be in contact with the lower surface PG-B of the pattern glass PG, or the lower surface of each of the plurality of second filling patterns FP2. The second flat portion TP2 may have a thickness T2 of about 0.01 μm to about 0.2 μm. For example, the second flat portion TP2 may have a thickness T2 of about 0.1 μm to about 0.2 μm. The second flat portion TP2 may correspond to the folding region FA2, and may be disposed so as to entirely overlap the folding region FA2. However, a shape of the second flat portion TP2 is not limited thereto, and in another embodiment, the second flat portion TP2 may be disposed so as to overlap a portion of the folding region FA2. Alternatively, in another embodiment, the first flat portion TP1 may entirely overlap the folding region FA2, and may be disposed so as to overlap a portion of the non-folding regions NFA3 and NFA4 (see FIG. 5B).

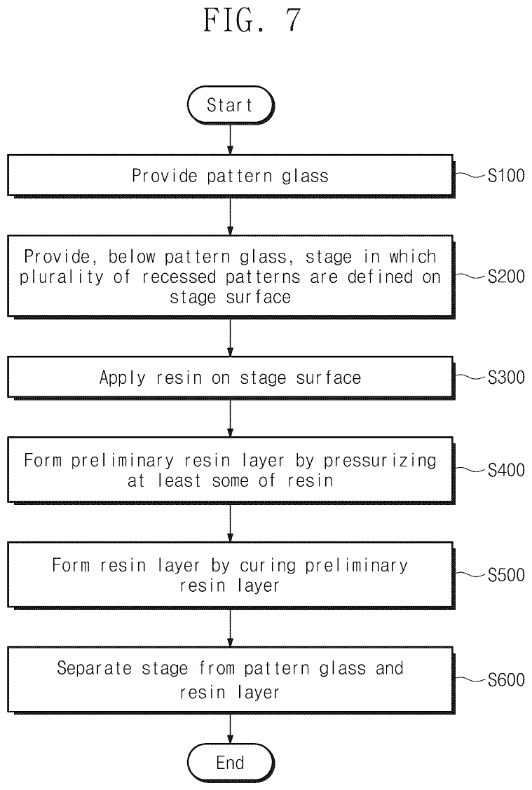

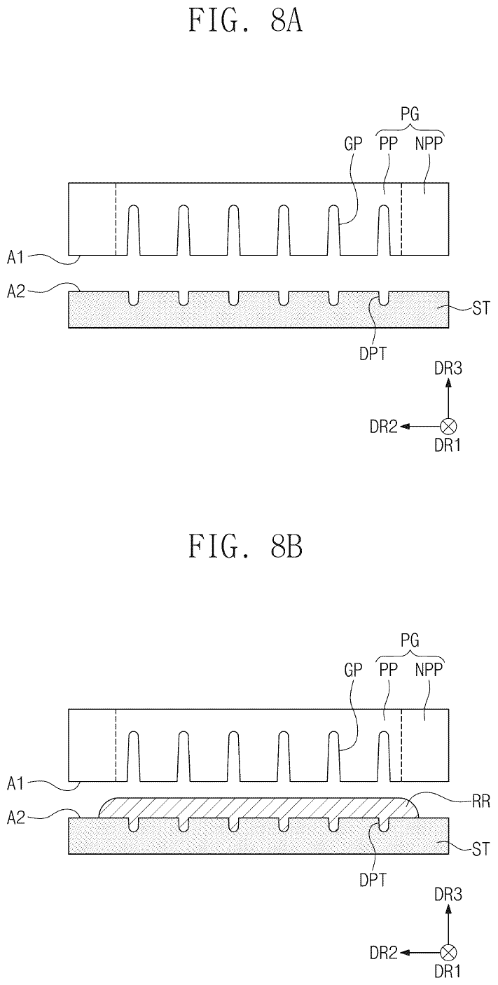

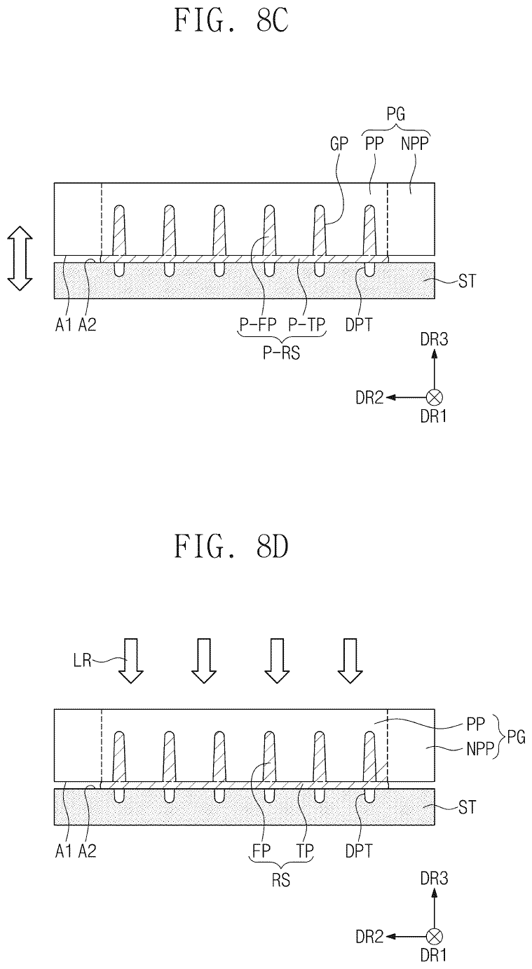

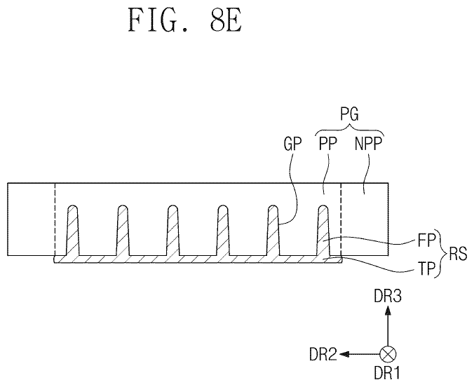

FIG. 7 is a flowchart showing a method of manufacturing a window according to an embodiment of the inventive concept. FIGS. 8A to 8E are cross-sectional views illustrating some steps of a method of manufacturing a window according to an embodiment of the inventive concept. Meanwhile, in the description of the method of manufacturing the window according to an embodiment of the inventive concept, the same reference numerals or symbols are used for the components duplicated with those described above, and a detailed description thereof will be omitted.

Referring to FIG. 7, the method of manufacturing the window according to an embodiment of the inventive concept includes steps of: providing a pattern glass (S100); providing, below the pattern glass, a stage in which a plurality of recessed patterns are defined on one surface (S200); applying a resin on one surface of the stage (S300); forming a preliminary resin layer by pressurizing at least some of the resin (S400); forming a resin layer by curing the preliminary resin layer (S500); and separating the stage from the pattern glass and the resin layer (S600).

In the method of manufacturing the window according to an embodiment of the inventive concept, FIG. 8A schematically illustrates the steps of providing a pattern glass (S100), and providing, below the pattern glass, a stage in which a plurality of recessed patterns are defined on one surface (S200), FIG. 8B schematically illustrates the step of applying a resin on one surface of the stage (S300), FIG. 8C schematically illustrates the step of forming a preliminary resin layer by pressurizing at least some of the resin (S400), FIG. 8D schematically illustrates the step of forming a resin layer by curing the preliminary resin layer (S500), and FIG. 8E schematically illustrates the step of separating the stage from the pattern glass and the resin layer (S600).

Referring to FIGS. 7 and 8A, the method of manufacturing the window according to an embodiment of the inventive concept includes the steps of providing a pattern glass PG (S100), and providing, below the pattern glass PG, a stage ST in which a plurality of recessed patterns DPT are defined on one surface A2 (S200).

The pattern glass PG includes a patterned portion PP at least a portion of which is folded, and a non-patterned portion NPP adjacent to the patterned portion PP. A plurality of groove patterns GP may be defined on one surface A1 of the patterned portion PP. For example, the plurality of groove patterns GP may be defined on a lower surface of the patterned portion PP. The patterned portion PP may be a portion corresponding to the above-described folding region FA2 (see FIG. 5B), and the non-patterned portion NPP may be a portion corresponding to the above-described non-folding regions NFA3 and NFA4 (see FIG. 5B).

A plurality of recessed patterns DPT may be defined on one surface A2 of the stage ST. For example, the plurality of recessed patterns DPT may be defined on an upper surface of the stage ST. The plurality of recessed patterns DPT may respectively correspond to the plurality of groove patterns GP. Spaces recessed due to the plurality of groove patterns GP and spaces recessed due to the plurality of recessed patterns DPT may be formed to face each other in the third direction DR3. The plurality of recessed patterns DPT may have various shapes so as to be respectively connected to the plurality of groove patterns GP if necessary. The plurality of recessed patterns DPT may have various shapes without a limitation as long as the plurality of groove patterns GP may be filled with a resin RR to be described later (see FIG. 8B).

The plurality of recessed patterns DPT may each be hydrophobic. The plurality of recessed patterns DPT may each be super-hydrophobic. The plurality of recessed patterns DPT may each have a contact angle of about 150 degrees to about 180 degrees with respect to water. Surfaces of each of the plurality of recessed patterns DPT may each include a hydrophobic material. Surfaces of each of the plurality of recessed patterns DPT may each include a super-hydrophobic material. For example, the plurality of recessed patterns DPT may each include a fluorine-based compound. Alternatively, the plurality of recessed patterns DPT may each have a micro unevenness defined therein. For example, a micro unevenness having a diameter of about 1 nm to about 1000 nm may be defined in each of the plurality of recessed patterns DPT.

Referring to FIGS. 7 and 8B, the method of manufacturing the window according to an embodiment of the inventive concept includes the step of applying the resin RR on the one surface A2 of the stage ST (S300).

The resin RR may include an ultraviolet photocurable resin. The resin RR may include at least one selected from a urethane-based resin, an epoxy-based resin, a polyimide-based resin, a polyester-based resin, a polyether-based resin, an acrylate-based resin, an acrylonitrile-butadiene-styrene resin (ABS resin), and rubber. Specifically, an organic material included in each of the first resin layer RS1 and the second resin layer RS2 may include at least one of phenylene, polyethyleneterephthalate (PET), polyimide (PI), polyamide (PAI), polyethylene naphthalate (PEN), or polycarbonate (PC).

Referring to FIGS. 7, 8B, and 8C, the method of manufacturing the window according to an embodiment of the inventive concept includes the step of forming a preliminary resin layer P-RS by pressurizing at least some of the resin RR (S400).

The step of forming the preliminary resin layer P-RS (S400) includes a step of moving the pattern glass PG in a direction of getting closer to the stage ST, and pressurizing at least some of the resin RR. The step of forming the preliminary resin layer P-RS (S400) may include a step of moving the pattern glass PG in a direction opposed to the third direction DR3, and pressurizing an upper surface of the resin RR via one surface A1 of the pattern glass PG with respect to the direction opposed to the third direction DR3.

In the step of forming the preliminary resin layer P-RS (S400), the resin RR may be detached from the recessed pattern DPT and be in contact with the groove pattern GP. Hydrophobicity of each of the plurality of recessed patterns DPT may be greater than hydrophobicity of each of the plurality of groove patterns GP. A contact angle of each of the plurality of recessed patterns DPT with respect to the resin RR may be greater than a contact angle of each of the plurality of groove patterns GP with respect to the resin RR. Following the step of applying the resin RR on the one surface of the stage (S300), the resin RR is disposed in the recessed patterns DPT of the stage ST. In the step of forming the preliminary resin layer P-RS (S400), the resin RR may fill the groove pattern GP and release from the recessed patterns DPT of the stage ST.

The preliminary resin layer P-RS may include a plurality of preliminary filling patterns P-FP and a preliminary flat portion P-TP. The preliminary resin layer P-RS may be spaced apart from the plurality of recessed patterns DPT. The plurality of preliminary filling pattern P-FP of the preliminary resin layer P-RS may be defined to fill the plurality of groove patterns GP, respectively. The preliminary flat portion P-TP may be directly disposed below the pattern glass PG, and the plurality of preliminary filling patterns P-FP.

Referring to FIGS. 7, 8C, and 8D, the method of manufacturing the window according to an embodiment of the inventive concept includes the step of forming a resin layer RS by curing the preliminary resin layer P-RS (S500).

The resin layer RS may include a plurality of filling patterns FP and a flat portion TP. The step of forming the resin layer RS (S500) includes a step of curing the preliminary resin layer P-RS. The step of forming the resin layer RS (S500) may include steps of forming the plurality of filling patterns FP by curing each of the plurality of preliminary filling patterns P-FP, and forming the flat portion TP by curing the preliminary flat portion P-TP. The step of forming the plurality of filling patterns FP by curing each of the plurality of preliminary filling patterns P-FP, and the step of forming the flat portion TP by curing the preliminary flat portion P-TP may not be performed through a separate process but through the same process at the same time.

The step of forming the resin layer RS (S500) may include a step of photocuring the preliminary resin layer P-RS by irradiating the pattern glass PG with ultraviolet rays LR. The ultraviolet rays LR may pass through the transparent pattern glass PG to be provided to the preliminary resin layer P-RS. The preliminary resin layer P-RS may include an ultraviolet photocurable resin, and the resin layer RS may be formed by curing the preliminary resin layer P-RS through UV irradiation.

Referring to FIGS. 7 and 8E, the method of manufacturing the window according to an embodiment of the inventive concept includes the step of separating the stage ST (see FIG. 8D) from the pattern glass PG and the resin layer RS (S600).

The stage ST (see FIG. 8D) may be separated from the pattern glass PG and the resin layer RS, and the pattern glass PG and the resin layer RS may be coupled to adjacent members such as the above-described window protective layer PL (see FIG. 5B) or the anti-reflection layer RPL (see FIG. 5B). Accordingly, the pattern glass PG and the resin layer RS may be included in the window WM (see FIG. 4) according to an embodiment of the inventive concept, and the display device DD (see FIG. 4) according to an embodiment of the inventive concept.

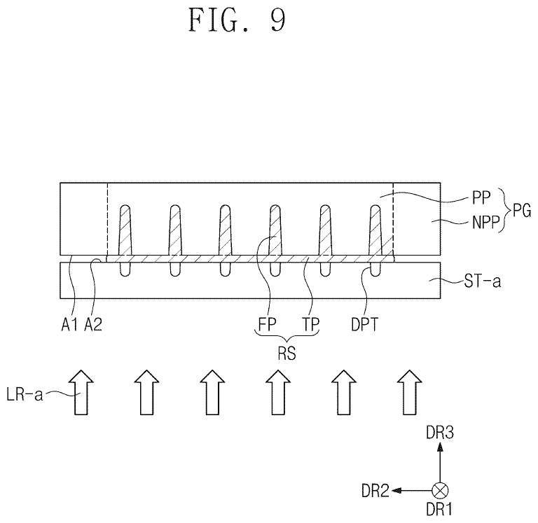

FIG. 9 is a cross-sectional view illustrating some step of a method of manufacturing a window according to another embodiment of the inventive concept. Compared to FIG. 8D, FIG. 9 schematically illustrates a step of forming a resin layer by curing a preliminary resin layer according to another embodiment of the inventive concept.

Referring to FIGS. 9, 7, and 8C together, the step of forming the resin layer RS (S500) may include a step of photocuring the preliminary resin layer P-RS by irradiating a lower part of a stage ST-a with ultraviolet rays LR-a. The stage ST-a may have a transmittance of about 90% or more with respect to the ultraviolet rays LR-a, and the ultraviolet rays LR-a may pass through the stage ST-a to be provided to the preliminary resin layer P-RS. The preliminary resin layer P-RS may include an ultraviolet photocurable resin, and the resin layer RS may be formed by curing the preliminary resin layer P-RS through UV irradiation.

In a window according to an embodiment of the inventive concept, a filling resin layer is formed in a pattern glass using a stage in which recessed patterns are defined, thereby improving reliability. Specifically, since the recessed patterns defined in the stage have hydrophobicity, the resin layer may be anti-stuck to the recessed patterns, and fill groove patterns defined in the pattern glass. In an embodiment, a space recessed due to a groove pattern may be provided in plurality, and the resin layer may not overfill or underfill but entirely fill each of the above-described recessed spaces. When the resin layer is manufactured through a curing process, there is a limitation that underfilling, etc., may occur according to curing shrinkage rates. However, in this inventive concept, since a window is manufactured to have a first flat portion which is formed by using a stage through a casting method, the resin layer may not underfill but entirely fill each of the recessed spaces. Accordingly, even when the resin layer is included in the pattern glass, the filling uniformity of the resin layer may be improved, and thus the window may have improved visibility. Additionally, since a method of manufacturing a window according to an embodiment of the inventive concept includes a step of using a stage in which recessed patterns are defined, a separate process through which the underfilling or overfilling resin layer is compensated is unnecessary, and thus manufacturing process efficiencies may relatively increase. Since a method of manufacturing a window according to an embodiment of the inventive concept includes a step of using a stage, a resin layer is not exposed to oxygen during the process, and a resin thereof does not include oxidized substances. Therefore, a separate process such as oxide removal process is unnecessary, and manufacturing process efficiencies may relatively increase.

A window according to an embodiment of the inventive concept, and a display device including the same include a first resin layer including a first flat portion, and thus it is possible to overcome limitation of user visibility which may be caused by a patterned portion of a pattern glass.

A method of manufacturing a window according to an embodiment of the inventive concept includes a step of forming a resin layer by using a stage in which hydrophobic recessed patterns are defined, thereby making it possible to increase manufacturing efficiencies and improve visibility for a user of the window manufactured through the method according to an embodiment.

Although the embodiments of the inventive concept have been described, it is understood that the inventive concept should not be limited to these embodiments but various changes and modifications can be made by one ordinary skilled in the art within the spirit and scope of the inventive concept as hereinafter claimed. Therefore, the technical scope of the inventive concept is not limited to the contents described in the detailed description of the specification, but should be determined by the claims.

What is claimed is:

1. An electronic device comprising:
a display device including a folding region with respect to an imaginary folding axis on a plane and a non-folding region adjacent to the folding region; and
a power module supplying power to the display device,
wherein the display device comprises:
a display panel; and
a window disposed on the display panel,
wherein the window includes a pattern glass including a patterned portion which corresponds to the folding region and a non-patterned portion which is adjacent to the patterned portion and corresponds to the non-folding region, and a first resin layer disposed on the pattern glass,
a plurality of first groove patterns are defined on an upper surface of the patterned portion, and
the first resin layer includes a plurality of first filling patterns respectively filling the plurality of first groove patterns, and a first flat portion directly disposed on the plurality of first filling patterns and the patterned portion.

2. The electronic device of claim 1, wherein the first resin layer comprises an organic material, and
the organic material includes at least one of a urethane-based resin, an epoxy-based resin, a polyimide-based resin, a polyester-based resin, a polyether-based resin, an acrylate-based resin, or an ABS resin.

3. The electronic device of claim 2, wherein the organic material comprises an ultraviolet curable resin.

4. The electronic device of claim 2, wherein the first resin layer does not comprise the organic material at least a portion of which is oxidized.

5. The electronic device of claim 1, wherein the first flat portion entirely overlaps the folding region.

6. The electronic device of claim 1, wherein the first flat portion has a thickness of about 0.01 μm to about 0.2 μm.

7. The electronic device of claim 1, wherein the imaginary folding axis extends in a first direction,
the non-folding region comprises a first non-folding region and a second non-folding region spaced apart from each other in a second direction perpendicular to the first direction with the folding region therebetween, and
the plurality of first groove patterns are arranged to be spaced apart from each other in the second direction.

8. The electronic device of claim 1, wherein the window further comprises a second resin layer disposed on a lower part of the pattern glass,
a plurality of second groove patterns are defined on a lower surface of the patterned portion, and
the second resin layer includes a plurality of second filling patterns respectively filling the plurality of second groove patterns, and a second flat portion directly disposed below the plurality of second filling patterns and the patterned portion.

9. The electronic device of claim 1, wherein the window further comprises a window protective layer disposed on the first resin layer.

10. The electronic device of claim 1, further comprising an optical layer disposed between the window and the display panel.

11. A window comprising:
a pattern glass including a patterned portion in which a plurality of first groove patterns are defined on an upper surface and at least a portion of which is folded, and a non-patterned portion adjacent to the patterned portion; and
a first resin layer disposed on the pattern glass,
wherein the first resin layer includes
a plurality of first filling patterns filling each of the plurality of first groove patterns, and
a first flat portion directly disposed on the plurality of first filling patterns and the patterned portion.

12. A method of manufacturing a window, the method comprising:
providing a pattern glass including a patterned portion in which a plurality of groove patterns are defined on one surface and at least a portion of which is folded on a plane, and a non-patterned portion adjacent to the patterned portion;
providing, below the pattern glass, a stage in which a plurality of recessed patterns respectively corresponding to the plurality of groove patterns are defined on one surface;
applying a resin on the one surface of the stage;
forming a preliminary resin layer by moving the pattern glass in a direction of getting closer to the stage and pressurizing at least some of the resin;
forming a resin layer by curing the preliminary resin layer; and
separating the stage from the pattern glass and the resin layer.

13. The method of claim 12, wherein surfaces of the plurality of recessed patterns each comprise a hydrophobic material.

14. The method of claim 12, wherein the plurality of recessed patterns each have a contact angle of about 150 degrees to about 180 degrees with respect to water.

15. The method of claim 12, wherein a contact angle of each of the plurality of recessed patterns with respect to the resin is greater than a contact angle of each of the plurality of groove patterns with respect to the resin.

16. The method of claim 12, wherein the plurality of recessed patterns each have a micro unevenness defined therein.

17. The method of claim 12, wherein the preliminary resin layer comprises:
a plurality of preliminary filling patterns respectively filling the plurality of groove patterns; and
a preliminary flat portion directly disposed below the plurality of preliminary filling patterns and the patterned portion.

18. The method of claim 12, wherein the forming of the resin layer by curing the preliminary resin layer comprises:
forming a plurality of filling patterns by curing each of the plurality of preliminary filling patterns; and
forming a flat portion by curing the preliminary flat portion.

19. The method of claim 12, wherein the forming of the resin layer by curing the preliminary resin layer comprises photocuring the preliminary resin layer by irradiating the pattern glass with ultraviolet rays.

20. The method of claim 12, wherein the forming of the resin layer by curing the preliminary resin layer comprises photocuring the preliminary resin layer by irradiating a lower part of the stage with ultraviolet rays, and
the stage has a transmittance of about 90% or more with respect to the ultraviolet rays.
